(19) United States
(12) Patent Application Publication
(10) Pub. No.: US 2009/0047765 A1
(43) Pub. Date: Feb. 19, 2009

(54) METHOD OF MANUFACTURING NON-VOLATILE MEMORY

(75) Inventors: Hung-Mine Tsai, Kaohsiung City (TW); Ching-Nan Hsiao, Kaohsiung County (TW); Chung-Lin Huang, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 11/955,393

(22) Filed: Dec. 13, 2007

(30) Foreign Application Priority Data
Aug. 13, 2007 (TW) 96129848

(51) Int. Cl. H01L 21/336

(52) U.S. Cl. 438/264; 257/E21.422

(57) ABSTRACT

A method of manufacturing a non-volatile memory is provided. In the method, a first dielectric layer, a first conductive layer, and a first cap layer are formed sequentially on a substrate. The first cap layer and the first conductive layer are patterned to form first gate structures. A second dielectric layer is formed on the sidewall of the first gate structures, and a portion of the first dielectric layer is removed to expose the substrate between the first gate structures. An epitaxy layer is formed on the substrate between two first gate structures. A third dielectric layer is formed on the epitaxy layer. A second conductive layer is formed on the third dielectric layer. The first cap layer and a portion of the first conductive layer are removed to form second gate structures. Finally, a doped region is formed in the substrate at two sides of the second gate structures.

### CROSS-REFERENCE TO RELATED APPLICATION

This application claims the priority benefit of Taiwan application serial no. 96129848, filed on Aug. 13, 2007. The entirety of the above-mentioned patent application is hereby incorporated by reference herein and made a part of this specification.

### BACKGROUND OF THE INVENTION

1. Field of the Invention

The present invention relates to a method of manufacturing a semiconductor device, and more particularly, to a method of manufacturing a non-volatile memory.

2. Description of Related Art

A memory is a semiconductor device designed to store information or data. With the production of increasingly powerful microprocessors in computers, programs and calculations that are executed by software expand significantly. As a result, demands for high storage capacity memories increase correspondingly. An incentive to produce the memory with high storage capacity and low costs in order to satisfy the aforesaid requirements has now motivated semiconductor manufacturers to fabricate memory devices with great integrity.

Among various types of memory products, a non-volatile memory allows multiple data writing, reading and erasing operations. The stored data will be retained even after power to the memory device is removed. With these advantages, the non-volatile memory has become one of the most widely adopted memories for personal computers and electronic equipment.

FIG. 1 is a schematic cross-sectional view of a conventional non-volatile memory. Referring to FIG. 1, the non-volatile memory is disposed on a substrate 100. The non-volatile memory includes a gate structure 102 and doped regions 104. The gate structure 102 includes a gate dielectric layer 106, a control gate 108, a cap layer 110, tunneling dielectric layers 112, floating gates 114, spacers 116, and inter-gate dielectric layers 118.

In general, during the fabrication of the non-volatile memory, the tunneling dielectric layers 112 and the floating gates 114 disposed thereon are formed on the substrate 100 at first. Thereafter, the inter-gate dielectric layers 118, the gate dielectric layer 106, the control gate 108 and other components are sequentially formed between the floating gates 114.

However, because the gate dielectric layer 106 is usually formed by thermal oxidation the gate dielectric layer 106 is not only formed on the substrate 100 between the floating gates 114 but also extended below the floating gates 114, such that a bird's beak effect occurs. Thereby, a thickness of each of the tunneling dielectric layers 112 is increased, giving rise to an unsatisfactory movement of electrons during an operation of the non-volatile memory and reducing the work efficiency of the non-volatile memory.

On the other hand, with an increase of integrity, dimensions of the devices are continuously reduced. Besides, the spacer is usually formed between the floating gates and the control gate to prevent the bird's beak effect. Both of which arise from a short channel effect due to an insufficient channel length.

### SUMMARY OF THE INVENTION

In view of the foregoing, the present invention is directed to a method of manufacturing a non-volatile memory to prevent a bird's beak effect, and to resolve the issue regarding an increased thickness of a tunneling dielectric layer, and avoid a short channel effect.

The present invention provides a method of manufacturing a non-volatile memory. In the method, a first dielectric layer, a first conductive layer, and a first cap layer are formed sequentially on a substrate. The first cap layer and the first conductive layer are then patterned to form a plurality of first gate structures. A second dielectric layer is then formed on sidewalls of the first gate structures, and a portion of the first dielectric layer is removed to expose the substrate between the first gate structures. Thereafter, an epitaxy layer is formed on the substrate between two adjacent first gate structures. Next, a third dielectric layer is formed on the epitaxy layer. Afterwards, a second conductive layer is formed on the third dielectric layer. The first cap layer and a portion of the first conductive layer are then removed to form a plurality of second gate structures. Finally, a doped region is formed in the substrate at two sides of each of the second gate structures.

According to an embodiment of the present invention, a thickness of the epitaxy layer ranges from 200 Å to 300 Å, for example.

According to an embodiment of the present invention, the epitaxy layer is formed by performing a selective-epi growth (SEG) process, for example.

According to an embodiment of the present invention, the epitaxy layer is an epitaxial silicon layer, for example.

According to an embodiment of the present invention, after the second conductive layer is formed but before the first cap layer and a portion of the first conductive layer are removed, a portion of the second conductive layer is removed. Next, an oxidation process is performed on the residual second conductive layer, so as to form a second cap layer on the second conductive layer.

According to an embodiment of the present invention, the step of forming the second gate structures further comprises performing a first oxidation process on the first conductive layer and forming a spacer on the sidewall of the second conductive layer after removing the first cap layer but before removing a portion of the first conductive layer Next, a portion of the first conductive layer is removed with use of the spacer as a mask. After that, a second oxidation process is performed on the residual first conductive layer.

According to an embodiment of the present invention, a material of the spacer is silicon nitride, for example.

According to an embodiment of the present invention, the doped region is formed by performing an ion implantation process, for example.

According to an embodiment of the present invention, a material of the first conductive layer is doped polysilicon, for example.

According to an embodiment of the present invention, a material of the second conductive layer is doped polysilicon, for example.

According to an embodiment of the present invention, the step of forming the second dielectric layer and removing a portion of the first dielectric layer includes forming a dielectric material layer conformally on the substrate at first. Thereafter, a dry etching process is implemented.

In the present invention, before the dielectric layer serving as a gate dielectric layer is formed by thermal oxidation, the epitaxy layer is formed on the substrate, and the dielectric layer is then formed on the epitaxy layer. Thereby, the dielectric layer can be avoided from being expended below the first gate structures during thermal oxidation, thus avoiding the occurrence of the bird's beak effect. Moreover, through the epitaxy layer disposed on the substrate, a channel length is increased, and shortcomings associated with the short channel effect are then overcome.

In order to make the aforementioned and other objects, features and advantages of the present invention more comprehensible, an embodiment accompanied with figures is described in detail below.

### BRIEF DESCRIPTION OF THE DRAWINGS

FIG. 1 is a schematic cross-sectional view of a conventional non-volatile memory.

FIGS. 2A through 2E are cross-sectional views illustrating a process of manufacturing a non-volatile memory according to an embodiment of the present invention.

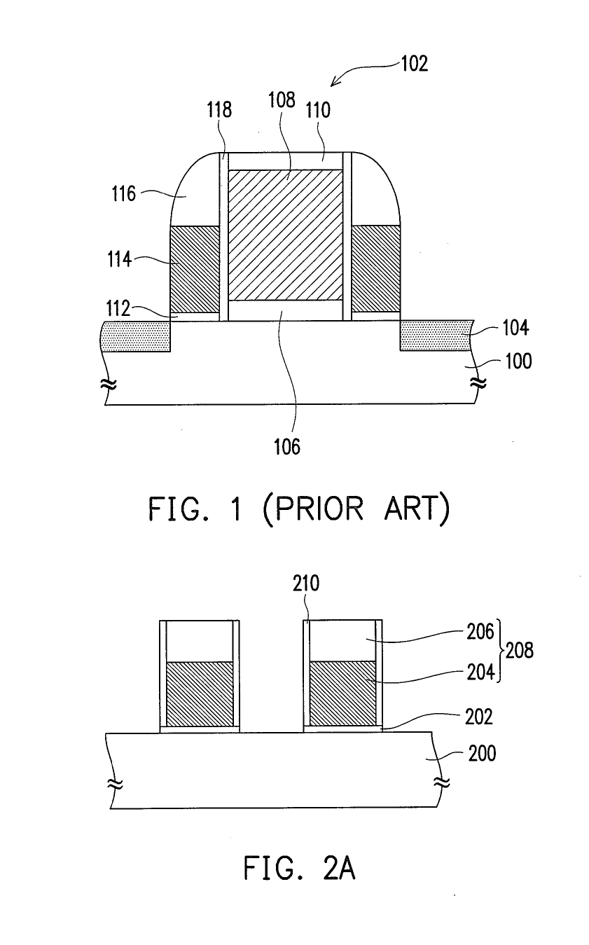

### DESCRIPTION OF EMBODIMENTS

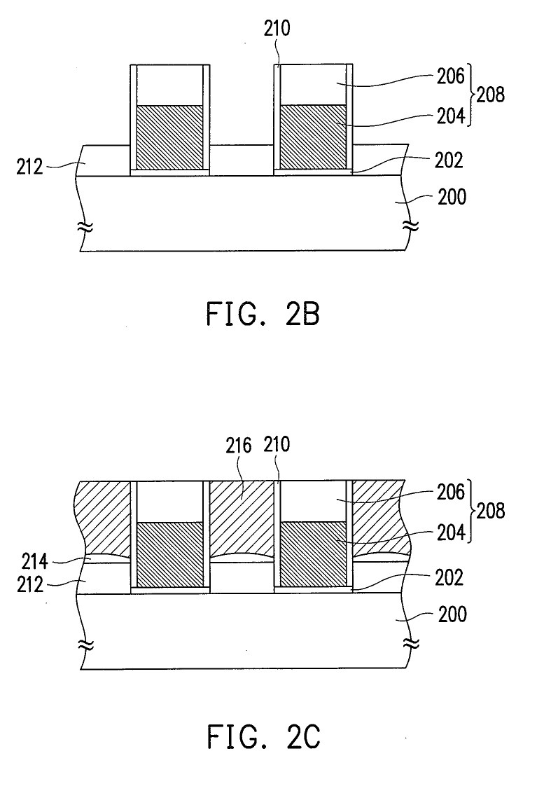

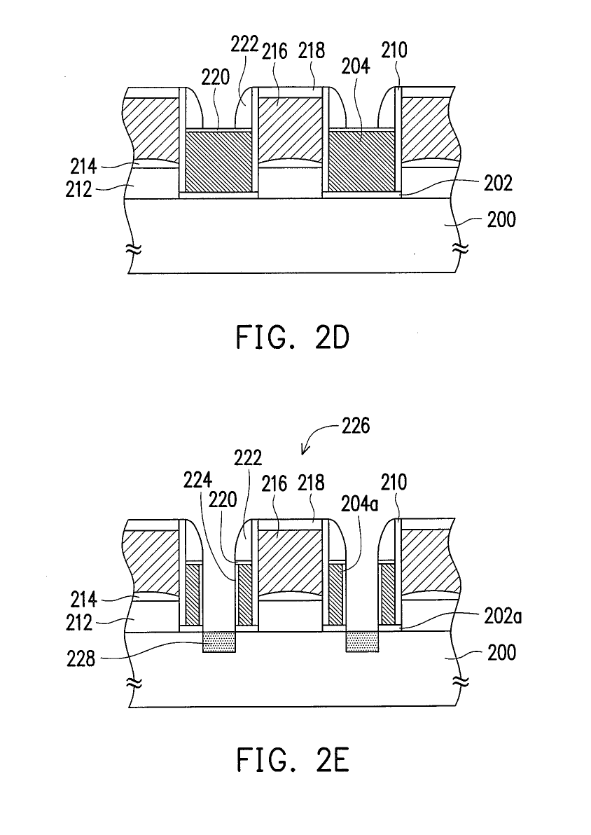

FIGS. 2A through 2E are cross-sectional views illustrating a process of manufacturing a non-volatile memory according to an embodiment of the present invention.

First, referring to FIG. 2A, a dielectric layer 202, a conductive layer 204, and a cap layer 206 are sequentially formed on a substrate 200. The dielectric layer 202 may contain, for example, silicon oxide, and be formed by, for example, thermal oxidation. The conductive layer 204 may contain, for example, doped polysilicon, and be formed by, for example, performing a chemical vapor deposition (CVD) process. The cap layer 206 may contain, for example, silicon nitride, and be formed by performing the CVD process.

Referring to FIG. 2A, a photolithography process and an etching process are implemented to pattern the cap layer 206, such that the patterned cap layer 206 is formed. Thereafter, the etching process is performed with the patterned cap layer 206 functioning as an etching mask, such that the patterned conductive layer 204 is formed. Here, the patterned cap layer 206 and the patterned conductive layer 204 together form gate structures 208. After that, a dielectric material layer is conformally formed on the substrate 200. In the present invention, the dielectric material layer is a composite layer formed by silicon oxide/silicon nitride/silicon oxide. The dielectric material layer is formed by forming a first silicon oxide layer through performing a thermal oxidation process at first, for example. Next, a silicon nitride layer is formed on the first silicon oxide layer by performing a CVD process. A second silicon oxide layer is then formed on the silicon nitride layer by performing a CVD process as well. However, in other embodiments, the dielectric material layer may also be made of silicon oxide. After that, a dry etching process is carried out, for example, to remove a portion of the dielectric material layer and the dielectric layer 202 disposed thereunder such that a dielectric layer 210 is formed on each sidewall of each of the gate structures 208. Hence, the substrate 200 between two gate structures 208 is exposed. The dielectric layer 210 disposed on each sidewall of the respective gate structure 208 serves as an inter-gate dielectric layer in the non-volatile memory.

Next, referring to FIG. 2B, an epitaxy layer 212 is formed on the substrate 200 between two adjacent gate structures 208. The epitaxy layer 212 is, for example, an epitaxial silicon layer, and a thickness of the epitaxy layer 212 ranges from 200 Å to 300 Å, for example. A method of forming the epitaxy layer 212 includes performing an SEG process, for example. In this step, the region of a to-be-formed gate dielectric layer (i.e. the surface of the substrate 200) is raised by the formation of the epitaxy layer, 212 on the substrate 200, so as to prevent the gate dielectric layer from adversely affecting the device. In addition, the epitaxy layer 212 is also conducive to increase the channel length of the device.

After that, referring to FIG. 2C, a dielectric layer 214 is formed on the epitaxy layer 212 through thermal oxidation. The dielectric layer 214 serves as the gate dielectric layer in the non-volatile memory. Note that the dielectric layer 214 is formed on the epitaxy layer 212 and positioned at a level higher than that of the dielectric layer 202. Hence, no bird's beak effect occurs during the formation of the dielectric layer 214, which causes a thickness of the dielectric layer 202 disposed below the patterned conductive layer 204 to increase. In addition, the thickness of the epitaxy layer 212 should be determined upon actual demands. Namely, even though the formation of the epitaxy layer 212 precludes an occurrence of the bird's beak phenomenon and an increase in the channel length, the epitaxy layer 212 having an excessively large thickness may give rise to a decrease in a coupling ratio.

Referring to FIG. 2C, a conductive material layer (not shown) made of doped polysilicon is deposited onto the substrate 200, and a chemical mechanical polishing (CMP) process is then implemented until the cap layer 206 is exposed, so as to form a conductive layer 216 on the dielectric layer 214. Here, the conductive layer 216 serves as a control gate in the non-volatile memory.

After that, referring to FIG. 2D, an etch back process is implemented to remove a portion of the conductive layer 216. Next, an oxidation process is performed on the residual conductive layer 216 to form a cap layer 218 on the conductive layer 216. Thereafter, the cap layer 206 is removed. The oxidation process is then performed on the conductive layer 204 to form an oxide layer 220 on the conductive layer 204. Afterwards, a spacer material layer (not shown) is conformally formed on the substrate 200. A material of the spacer material layer is, for example, silicon nitride. Next, a dry etching process is implemented to remove a portion of the spacer material layer, for example. Thereby, a spacer 222 is formed on each sidewall of the conductive layer 216.

After that, referring to FIG. 2E, with use of the spacer 222 as the etching mask, a portion of the oxide layer 220 is removed along with the conductive layer 204 as well as the dielectric layer 202, which are both disposed below the oxide layer 220, so as to expose the substrate 200, and to form conductive layers 204a serving as floating gates in the non-volatile memory and dielectric layers 202a serving as tunneling dielectric layers. Next, the oxidation process is performed on the conductive layers 204a for forming oxide layers 224. As such, the fabrication of gate structures 226 in the non-volatile memory is completed. Thereafter, an ion implantation process is performed on the substrate 200 at two sides of the gate structures 226, so as to form a doped region 228 in the substrate 200 at two sides of the gate structures 226, and the fabrication of the non-volatile memory is then completed.

To sum up, in the present invention, before the gate dielectric layer disposed below the control gate is formed by thermal oxidation, the epitaxy layer is formed on the substrate, and the gate dielectric layer is then formed on the epitaxy layer. Thereby, the gate dielectric layer is avoided from being extended below the tunneling dielectric layer during thermal oxidation, and no bird's beak phenomenon takes place. Besides, the thickness of the tunneling dielectric layer is prevented from increasing and adversely affecting performance of the device.

Furthermore, the formation of the epitaxy layer on the substrate contributes to the increase in the channel length, thus avoiding the short channel effect.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a non-volatile memory, the method comprising:
forming a first dielectric layer, a first conductive layer, and a first cap layer sequentially on a substrate;
patterning the first cap layer, and the first conductive layer to form a plurality of first gate structures;
forming a second dielectric layer on sidewalls of the first gate structures and removing a portion of the first dielectric layer to expose an area of the substrate between the two adjacent first gate structures;
forming an epitaxy layer on the substrate between the two adjacent first gate structures;
forming a third dielectric layer on the epitaxy layer;
forming a second conductive layer on the third dielectric layer;
removing the first cap layer and a portion of the first conductive layer to form a plurality of second gate structures; and
forming a doped region in the substrate at two sides of the second gate structures.

2. The method of claim 1, wherein a thickness of the epitaxy layer ranges from 200 Å to 300 Å.

3. The method of claim 1, wherein the step of forming the epitaxy layer comprises performing a selective-epi growth (SEG) process.

4. The method of claim 1, wherein the epitaxy layer comprises an epitaxial silicon layer.

5. The method of claim 1, wherein after the second conductive layer is formed but before the first cap layer and a portion of the first conductive layer are removed, the method further comprises:
removing a portion of the second conductive layer; and
performing an oxidation process on the residual second conductive layer, such that a second cap layer is formed on the second conductive layer.

6. The method of claim 1, wherein the step of forming the second gate structures further comprises:
performing a first oxidation process on the first conductive layer and forming a spacer on the sidewall of the second conductive layer after removing the first cap layer and before removing a portion of the first conductive layer;
removing a portion of the first conductive layer with use of the spacer as a mask; and
performing a second oxidation process on the residual first conductive layer.

7. The method of claim 6, wherein a material of the spacer comprises silicon nitride.

8. The method of claim 7, wherein the step of forming the doped region comprises performing an ion implantation process.

9. The method of claim 8, wherein a material of the first conductive layer comprises doped polysilicon.

10. The method of claim 6, wherein a material of the second conductive layer comprises doped polysilicon.

11. The method of claim 6, wherein the step of forming the second dielectric layer and removing a portion of the first dielectric layer comprises:
conformlly forming a dielectric material layer on the substrate; and
performing a dry etching process.
